(19) United States
(12) Patent Application Publication
(10) Pub. No.: US 2024/0046013 A1
(43) Pub. Date: Feb. 8, 2024

(54) CHIP PLACEMENT METHOD AND APPARATUS, AND STORAGE MEDIUM

(71) Applicant: The University of Hong Kong, Hong Kong (CN)

(72) Inventors: Ping Luo, Hong Kong (CN); Yao Lai, Hong Kong (CN); Yao Mu, Hong Kong (CN)

(73) Assignee: The University of Hong Kong, Hong Kong (CN)

(21) Appl. No.: 18/355,754

(22) Filed: Jul. 20, 2023

Related U.S. Application Data
(60) Provisional application No. 63/396,053, filed on Aug. 8, 2022.

(51) Int. Cl. G06F 30/32; G06T 7/60; G06T 7/11; G06T 7/73; G06T 7/00

(52) U.S. Cl. CPC G06F 30/32; G06T 7/60; G06T 7/11; G06T 7/74; G06T 7/001; G06T 2207/20084; G06T 2207/30148

(57) ABSTRACT

A chip placement method includes the steps of: (a) determining the order of placement of integrated circuit chips by the features of the chip modules, (b) generating pix-level masks from the status of the placed chips and the next two chips to be placed, (c) extracting local and global features from the masks by convolutional neural networks, and (d) selecting the placement position by merged features and a congestion threshold. The method is carried out by computer apparatus with a storage medium.

### CROSS-REFERENCE TO RELATED PATENT APPLICATION

This application is a U.S. non-provisional application claiming the benefit of priority under 35 U.S.C. Section 119(e) of U.S. Application No. 63/396,053, filed Aug. 8, 2022, which is incorporated by reference in its entirety.

### FIELD OF THE INVENTION

The present invention relates to the field of electronic design automation technologies, and in particular, to a chip placement method and apparatus, an electronic device and a storage medium.

### BACKGROUND OF THE INVENTION

Placement of integrated circuit chips in various applications may involve placing millions of circuit modules on a 2D chip canvas or circuit board. Such placement is time-consuming and expensive because it requires the involvement of hardware experts in order to achieve better chip performance, e.g., avoiding long circuit paths between chip modules. Deep learning technology employing neural networks can be applied to overcome such difficulties. Due to the chip placement problem having domain characteristics, original features need to be pre-processed to obtain various masks before inputting data into the neural network. The neural network can learn is the location of the most suitable position for the module to be placed according to the current state of the design. In this process, different convolutional kernel sizes in the neural network can extract local and global features.

Prior techniques for chip placement include Lin et al., “DREAMPlace: Deep Learning Toolkit-Enabled GPU Acceleration for Modern VLSI Placement, IEEE Transactions on Computer-Aided Design of Integrated Circuits and Systems, 40(4), 748-761, which is a classic optimization-based method (not a learning-based method). The article Mirhoseini et al., “A graph placement methodology for fast chip design,” Nature, 2021, 594(7862):207-212 describes a graphical neural network-based method. However; it cannot satisfy the no-overlapping constraint for chip placement. The article, Yan et al., “Towards Machine Learning for Placement and Routing in Chip Design: a Methodological Overview,” arXiv:2202.13564 (2022) presents a detailed review of recent advance in machine learning for placement and routing. However, it does not include a design method for generating position masks and wire masks. The article Alhyari et al., “A Deep Learning Framework to Predict Routability for FPGA Circuit Placement,” 2019 29th International Conference on Field Programmable Logic and Applications (FPL), Barcelona, Spain, 2019, pp. 334-341, doi:10.1109/FPL.2019.00060 discusses a novel, deep-learning framework based on a Convolutional Neural Network model for predicting the routability of a placement that incorporates the deep-learning model into a state-of-the-art placement tool, and shows how the model can be used to (1) avoid costly, but futile, place-and-route iterations, and (2) improve the placer's ability to produce routable placements for hard-to-route circuits using feedback based on routability estimates generated by the proposed model. The task of the method is to predict routability given a known placement plan, which is not suitable for generating a placement plan.

### SUMMARY OF THE INVENTION

The present invention is directed to the field of computer vision, communication, and particularly relates to electronic design automation, including but not limited to a chip placement method and device, a computer device and a storage medium. The invention provides a chip placement method that facilitates the placement of thousands of modules on a chip canvas with high performance and efficiency. It extracts features of the chip modules and generates various masks which can contain information for the placement of the modules and determines place positions from these masks by convolutional neural networks.

A first aspect of an embodiment of the invention provides a chip placement method, which may include the following operations:
(A) The order of placement is determined by the features of the modules.
(B) Pix-level masks are generated from the features of the placed modules and the next two modules to be placed.
(C) Local and global features are extracted from masks from neural networks.
(D) Final place position action is selected by high-level features and congestion status.

A second aspect of an embodiment of the invention provides a chip placement apparatus, which includes a processor and a memory for storing instructions executable by the processor. The processor is configured to perform the operations of the chip placement method.

A third aspect of an embodiment of the invention provides a storage medium, having stored therein computer instructions that, when being executed by a processor, cause the processor to implement the operations of the chip placement method.

The invention provides better chip placement performance and meets chip design constraints. The diverse masks used with the invention can help neural networks obtain essential information for placement and satisfy constraints on placement. Multi-scale feature extraction can avoid the diffusion of location information. A reward design scheme is employed to avoid sparse rewards that are difficult to train. Chips placed according to the invention have better performance (shorter wirelength) and meet constraints that are difficult to meet with other methods (e.g., no module overlap in the design).

### BRIEF DESCRIPTION OF THE DRAWINGS

The foregoing and other objects and advantages of the present invention will become more apparent when considered in connection with the following detailed description and appended drawings in which like designations denote like elements in the various views, and wherein:

FIG. 1 is an implementation flowchart of a chip placement method according to a first embodiment of the present invention;

FIG. 2 is an implementation flowchart of a chip placement method according to a second embodiment of the present invention;

FIG. 3 is an implementation flowchart of a chip placement method according to a third embodiment of the present invention;

FIG. 4 is a schematic diagram of a position mask obtained based on positions of placed modules and the size of the module to be placed;

FIG. 5 is schematic diagram of a wire mask obtained based on distances between modules;

FIG. 6 is an implementation flowchart of a chip placement method according to a fourth embodiment of the present invention;

FIG. 7 is an implementation flowchart of a chip placement method according to a fifth embodiment of the present invention;

FIG. 8 is an implementation flowchart of a chip placement method according to a sixth embodiment of the present invention;

FIG. 9 is a composition structure diagram of a chip placement device according to one embodiment of the present invention;

FIG. 10 is a composition structure diagram of a computer device according to another embodiment of the present invention; and

FIG. 11 is a schematic diagram showing movement of the bounding box in the opposite direction of the pin of the module to be placed relative to its coordinate position to unify the relative positions of different pins.

### DETAILED DESCRIPTION OF THE INVENTION

In order to make the purposes, technical solutions and advantages of the embodiments of the invention clearer, specific technical solutions of the invention will further be described in detail below in combination with the drawings of the embodiments of the invention. The following embodiments are adopted to describe the invention but are not intended to limit the scope of the invention.

The present invention includes a chip placement method, which enables the user to select the most suitable location (position) for each chip module, so that chip performance can be optimized and at the same time, the design can comply with chip design constraints. The method is applied by means of a computer device, and the functions realized by the method may be realized by calling a program code through a processor in the computer device. Of course, the program code may be stored in a computer storage medium. Thus, the computer device at least includes the processor and the storage medium.

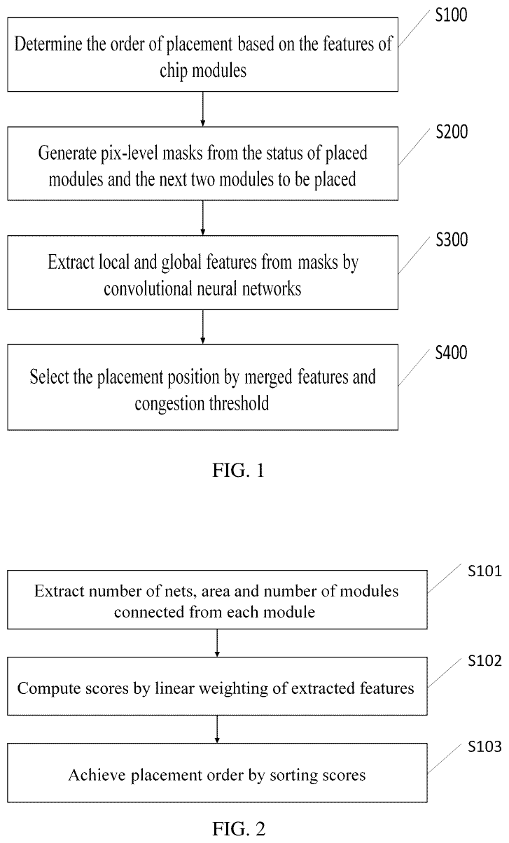

As shown in FIG. 1, the chip placement method of a first embodiment of the invention includes the steps of: (a) determining the order of placement by the features of the chip modules (step S100), (b) generating pix-level masks from the status of the placed modules and the next two modules to be placed (step S200), (c) extracting local and global features from the masks by convolutional neural networks (step S300) and (d) selecting the placement position by merged features and congestion threshold (step S400).

FIG. 2 is an implementation flowchart of the chip placement method according to a second embodiment of the invention. As shown in FIG. 2, the method includes the following steps:

In step S101, the features of the modules to be placed are acquired, including the number of pins (nets) (f1) and modules (f2) they are connected to, and their area (f3). The operation of step S101 may be implemented by a computer device.

In step S102, a score is calculated for each module by the weighted sum of normalized features. The score equals α1f1+α2f2 +α3f3, where α1,α2,α3 are definable weights of each feature.

In step S103, a sorting algorithm is implemented on the scores achieved in step S102. The order of the scores from largest to smallest determines the order of the placement of the modules.

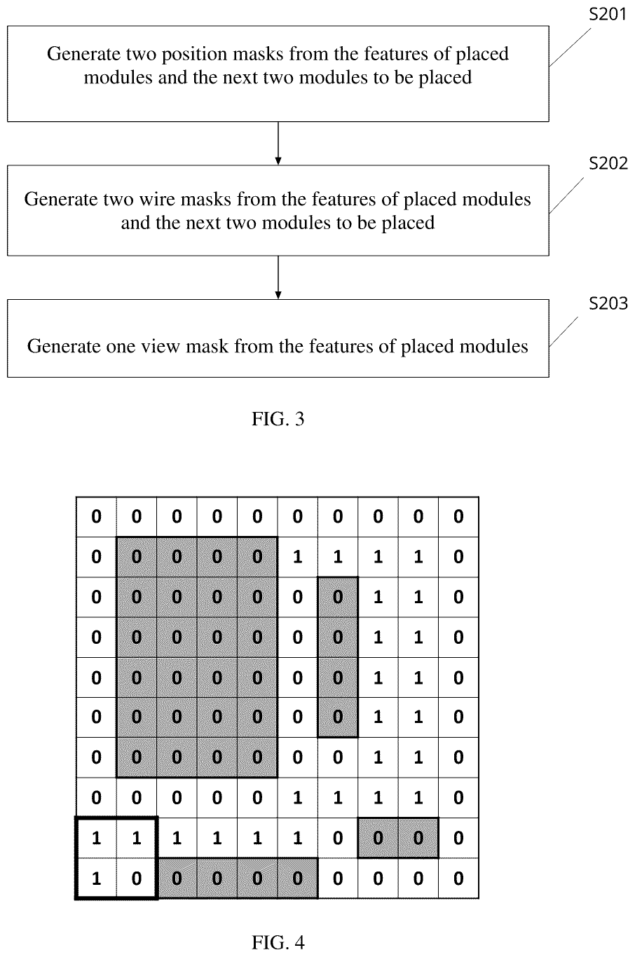

A third embodiment of the invention provides a chip placement method. FIG. 3 is an implementation flowchart of a chip placement method according to that embodiment of the invention. As shown in FIG. 3, the method includes the following steps.

In step S201, the features of the placed modules and the next two modules to be placed are acquired, including the width, height, and position of the modules. Then, the next two modules are slid on the chip canvas. If the next module cannot overlap with existing placed modules, the corresponding position on the mask is marked as 1. Otherwise, it is marked as 0. If one module occupies more than one element in the mask, the leftmost element it occupies is marked as the status of a module as placeable or not. Then, step S201 generates two position masks for the next two modules separately. As shown in FIG. 4, there are four placed modules, which are in grey. The next module to be placed occupies 2×2 elements, and its shape is shown as a black border. Then, it is slid across the chip canvas and its position is marked with a 1 at that position (the lower left element occupied by the corresponding module), if it does not overlap with any other placed modules.

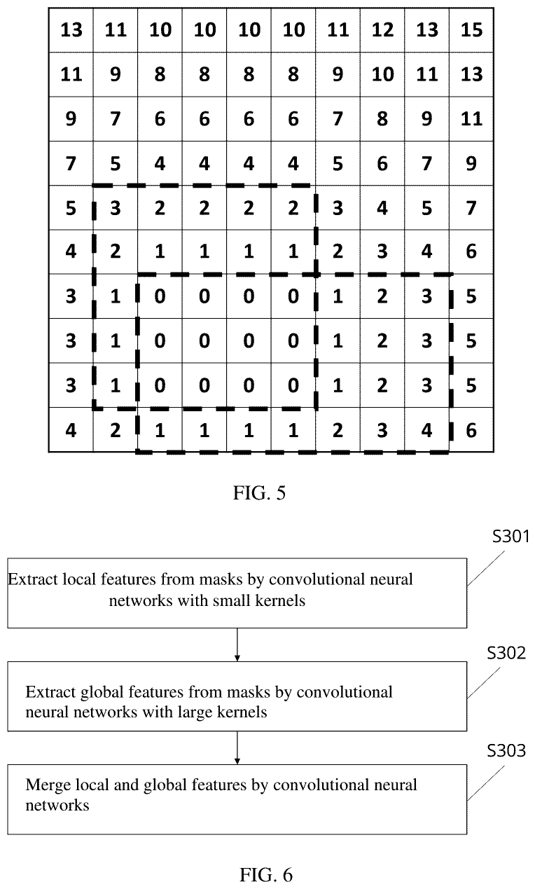

In step S202, the features of modules to be placed are acquired, including the width, height and pin locations of the modules. All pins connected by the same wire (i.e., belong to the same net) generate a bounding box. Then, two wire masks are generated by the accumulation of the shortest distance from each element in the mask to the bounding box. Each wire mask accumulates only the bounding box of the pins to which the module is connected. As shown in FIG. 5, there are two bounding boxes indicated by dashed lines which mark the maximum range of pins connected to the same wire. The corresponding number in the wire mask is the sum of the Manhattan distances from the position to the two bounding boxes, or 0 if the position is inside the bounding box, where the Manhattan distance is the distance between two points in a N dimensional vector space, i.e., the sum of the lengths of the projections of the line segment between the points onto the coordinate axes. For example, the value of the top-left element of this wire mask is 13, and its Manhattan distances to the two bounding boxes without moving diagonally are 5 and 8, respectively. To make the calculation more accurate, the bounding box needs to be moved. The direction of this movement is in the opposite direction of the pin of the module to be placed relative to its lower left coordinate position, as shown in FIG. 11 to unify the relative positions of different pins. Therefore, step S201 generates two wire masks which correspond to the next two modules to be placed.

In step S203, the features of modules to be placed are acquired, including the width, height, and positions of the modules. A view mask is generated by these placed modules, and each element in the mask indicates whether the position is occupied by a module. Each module with size w×h, covers [wN/W]×[hN/H] elements in the view mask, where W and H represent the chip canvas size, ┌.┐ denotes the ceiling function and N×N represents the size of view mask. If one element is occupied by one module, the corresponding element is marked by 1 and otherwise it is marked by 0. Therefore, step S203 generates one view mask to represent the current placement status.

A fourth embodiment provides a chip placement method. FIG. 6 is an implementation flowchart of this chip placement method according to the invention. As shown in FIG. 6, the method includes the following steps:

In step S301, two position masks and two wire masks are acquired. Local features of the placement status are extracted by small convolution kernels. Then, step S301 obtains a local feature map that has the same size as the position and wire masks.

In step S302, two wire masks and one view mask are acquired. Global features of the placement status are extracted by large convolution kernels. Then, step S302 obtains a global feature map that has the same size as the other masks.

In step S303, the global feature and the local feature are input in different channels and are merged by convolution layers in the channel dimension, where a convolutional layer consists of one or more channels and the number of channels is the depth of the matrices involved in the convolution. Then, the output of the neural network is normalized into a probability matrix by one softmax layer. The softmax function is used as the activation function in the output layer of neural network models that predict a multinomial probability distribution. That is, softmax is used as the activation function for multi-class classification problems where each class represents a place position in the chip placement task. Each element in the output matrix means the probability of the next macro will be placed in that position.

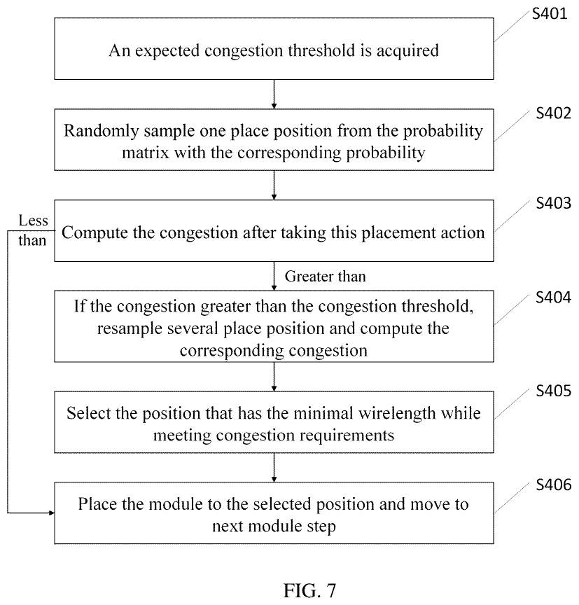

A fifth embodiment of the invention provides a chip placement method. FIG. 7 is an implementation flowchart of a chip placement method according to that embodiment of the invention. As shown in FIG. 7, the method includes the following steps.

In step S401, an expected congestion threshold is acquired, which defines the maximum congestion allowed by the design.

In step S402, one position for placing the module is sampled according to the probability matrix. In this process, illegal positions that would result in overlap of chips are removed directly before the sampling process.

In step S403, the congestion is computed with the new placement design after placing the next module in the sampled position.

If the congestion is smaller than the congestion threshold, the next module is placed according to the sampled place in step S406.

Otherwise, in step S404, some positions are re-sampled uniformly and the corresponding congestion and wirelength are computed.

In step S405, the position which has the shortest wirelength while satisfying the congestion threshold limit is selected.

In step S406, the next module is placed according to the selected position.

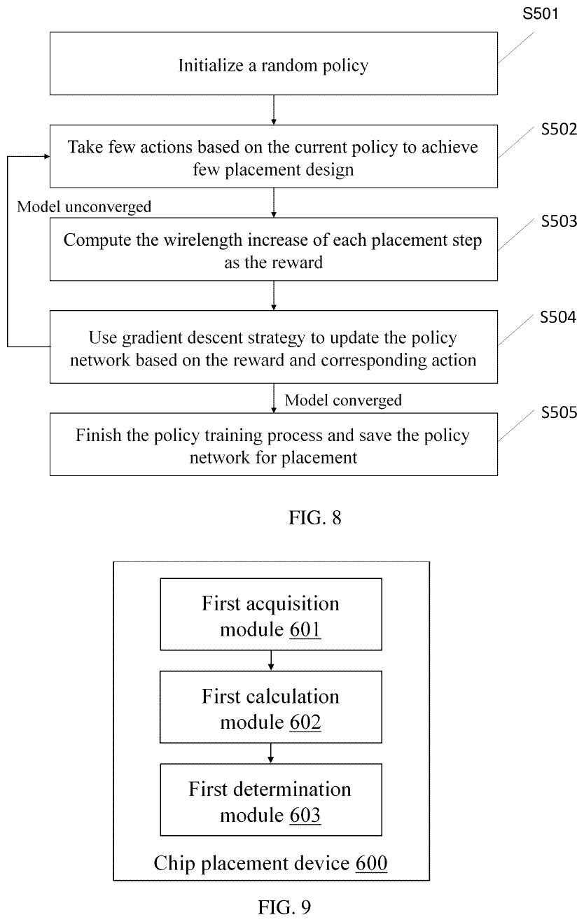

A sixth embodiment of the invention is a chip placement method as shown in FIG. 8, which is an implementation flowchart of a chip placement method according to that embodiment of the invention. As shown in FIG. 8, the method includes the following steps.

In step S501, a policy network is randomly initialized. The input of the network is the generated masks, and the output of the network is the probability matrix of placement positions.

In step S502, some actions are taken based on the policy network. In this process, some placement designs are saved based on a reinforcement learning framework.

In step S503, the wirelength increase for each action step is computed and is saved as the reward. In detail, the reward is defined as:

reward=wirelengthₜ₋₁−wirelengthₜ (1)

where wirelengthₜ is the wirelength after placing t modules.

In step S504, gradient descent strategy is used to update the policy network based on the reward and placement action. In detail, if the placement action can receive a higher reward, the policy model should increase the probability of this action, and conversely, if the reward is lowered the probability of the action needs to be reduced.

If the parameters of the model have converged, then the training process of the policy model is finished and the results are saved for placement. Otherwise, the policy model continues to update in step S502.

The embodiments of the invention provide a chip placement device. FIG. 9 is a composition structure diagram of such a chip placement device according to an embodiment of the invention. As shown in FIG. 9, the device 600 includes a first acquisition module 601, a first calculation module 602, and a first determination module 603. The first acquisition module 601 is configured to acquire the features of the chip to be processed. The first calculation module 602 is configured to compute the probability action matrix from extracted features of the chip. The first determination module 603 is configured to determine a target normalization manner according to the probability action matrix.

In the embodiment of the invention, the first acquisition module 601 includes a first extraction submodule configured to perform feature extraction on features of the chip by the use of prepossessing. Correspondingly, a pre-set parameter set includes a first hyper-parameter, a second hyper-parameter and a learning parameter.

The first calculation module 602 includes a first calculation submodule configured to calculate the final probability matrix according to the user defined hyper-parameter and learning parameter in the pre-set parameter set.

The first acquisition module 601 includes a first determination submodule configured to determine the score for each chip according to the acquired features and a second determination submodule configured to determine the placement order according to the scores computed in the first determination.

Correspondingly, the first calculation module 602 includes a first-generation submodule configured to correspondingly generate position masks, wire masks and view mask with the acquired features of modules. It further includes a first calculation submodule configured to compute the local and global feature matrix by convolution operations respectively; and a third determination submodule configured to determine the probability of placement in each position by the softmax layer based on the feature matrix.

Correspondingly, the first determination module 603 includes a fourth determination submodule configured to determine the final placement position according to the probability matrix and the user defined congestion threshold.

It is to be noted that, in the embodiments of the invention, when being implemented in the form of software function modules and sold or used as an independent product, the chip placement method may also be stored in a computer-readable storage medium. Based on such an understanding, the technical solutions of the embodiments of the invention substantially, or parts making contributions to the conventional art, may be embodied in the form of a software product. The computer software product may be stored in a storage medium, including a plurality of instructions for enabling an instant messaging device (which may be a terminal and a server, etc.) to perform all or part of the method in each embodiment of the invention. The storage medium includes various media capable of storing program codes such as a U disk, a mobile hard disk, a Read Only Memory (ROM), a magnetic disk or an optical disk. As a consequence, the embodiments of the invention are not limited to any specific hardware and software combination.

Correspondingly, the embodiments of the invention provide a computer storage medium, which stores computer-executable instructions that, when being executed, cause implementation of the steps of the chip placement method provided in the embodiments of the invention.

The embodiments of the invention provide a computer device, which includes a memory and a processor. The memory is configured to store computer executable instructions. The processor is configured to execute the computer executable instructions in the memory to implement the steps in the chip placement method provided in the embodiments of the invention.

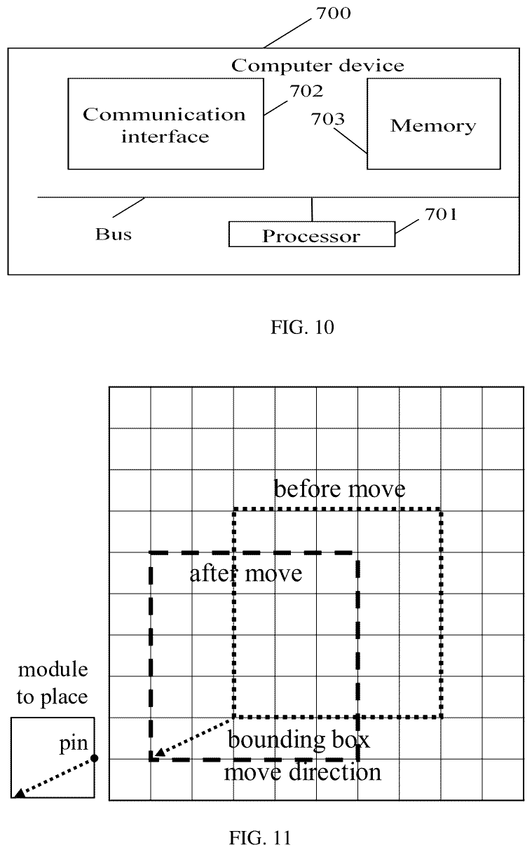

FIG. 10 is a composition structure diagram of a computer device according to an embodiment of the invention. As shown in FIG. 10, a hardware version of the computer device 700 includes a processor 701, communication interface 702 and a memory 703. The processor 701 usually controls an overall operation of the computer device 700. The communication interface 702 may enable the computer device to communicate with another terminal or server through a network. The memory 703 is configured to store instructions and applications executable by the processor 701 or may also cache data to be processed or having been processed by the processor 701 and each module in the computer device 700 or may be implemented through a flash or a Random Access Memory (RAM).

The above descriptions about the instant computer device and storage medium embodiments are similar to descriptions about the method embodiments and beneficial effects similar to those of the method embodiments are achieved. Technical details undisclosed in the instant communication device and storage medium embodiments of the invention may be understood with reference to the descriptions of the method embodiments of the invention.

It is to be understood that “one embodiment” and “an embodiment” mentioned in the whole specification mean that specific features, structures or characteristics related to the embodiment are included in at least one embodiment of the invention. Therefore, “in one embodiment” or “in an embodiment” appearing at any place in the whole specification does not always refer to the same embodiment. In addition, these specific features, structures or characteristics may be combined in one or more embodiments in any proper manner. It is to be understood that, in various embodiments of the invention, a magnitude of a sequence number of each process does not mean an execution sequence and the execution sequence of each process should be determined by its function and internal logic and should not form any limit on an implementation process of the embodiments of the invention. The sequence numbers of the embodiments of the invention are adopted not to represent superiority or inferiority of the embodiments, but only for description.

It is to be noted that terms “include” and “comprise” or any other variant thereof are intended to cover nonexclusive inclusions herein, so that a process, method, object or device including a series of elements not only includes those elements but also includes other elements which are not clearly listed or further includes elements intrinsic to the process, the method, the object or the device. Without more limitations, an element defined by the statement “including a/an” does not exclude the existence of the same other elements in a process, method, object or device including the element.

In some embodiments provided by the invention, it is to be understood that the disclosed device and method may be implemented in another manner. The device embodiment de scribed above is only schematic, and for example, division of the units is only logic function division, and other division manners may be adopted during practical implementation. For example, multiple units or components may be combined or integrated into another system, or some characteristics may be neglected or not executed. In addition, coupling, direct coupling or communication connection between various displayed or discussed components may be indirect coupling or communication connection, implemented through some interfaces of the device or the units, and may be electrical and mechanical or adopt other forms.

The units described as separate parts may or may not be physically separated, and parts displayed as units may or may not be physical units, namely they may be located in the same place, or may also be distributed to multiple network units. Part or all of the units may be selected according to a practical requirement to achieve the purposes of the solutions of the embodiments.

In addition, various functional units in each embodiment of the invention may be integrated into a processing unit, or serve as an independent unit, and two or more units may also be integrated into a unit. The integrated unit may be implemented in a hardware form or may be implemented in the form of hardware and software functional units.

Those of ordinary skill in the art should know that all or part of the steps of the method embodiments may be implemented by related hardware instructed by a program. The program may be stored in a computer-readable storage medium, and when being executed, implement the steps of the method embodiments. The storage medium includes various media capable of storing program codes, such as a mobile storage device, a ROM, a magnetic disk or a compact disc.

When being implemented in the form of software functional modules, and sold or used as an independent product, the integrated unit of the invention may also be stored in a computer-readable storage medium. Based on such an understanding, the technical solutions of the embodiments of the invention substantially, or parts making contributions to the conventional art, may be embodied in the form of a software product, and the computer software product is stored in a storage medium, including a plurality of instructions configured to enable a computer device (which may be a personal computer, a server or the like) to execute all or part of the method in various embodiments of the invention. The storage medium includes various media capable of storing program codes such as a mobile hard disk, a ROM, a magnetic disk or a compact disc.

The above is only the specific implementation mode of the invention and not intended to limit the scope of protection of the invention. Any modifications or substitutes apparent to those skilled in the art shall fall within the scope of protection of the invention. Therefore, the protected scope of the invention shall be subject to the scope of protection of the claims.

While the invention is explained in relation to certain embodiments, it is to be understood that various modifications thereof will become apparent to those skilled in the art upon reading the specification. Therefore, it is to be understood that the invention disclosed herein is intended to cover such modifications as fall within the scope of the appended claims.

1. A chip placement method, comprising the steps of:
determining the order of placement by features of the chip,
generating pix-level masks from the status of placed chips and the next two chips to be placed,
extracting local and global features from the masks by convolutional neural networks, and,
selecting the placement position by merged features and congestion threshold.

2. The method of claim 1, wherein determining the order of placement by the features of the chip comprises:
extracting the number of pins, the area and the number of chips connected to each chip;
computing scores by linear weighting of extracted features; and
achieving placement order by sorting the scores.

3. The method of claim 2, wherein computing scores by linear weighting of extracted features comprises:
acquiring the hyperparameter for each weight of each feature; and
calculating the weighted sum as score for each chip.

4. The method of claim 1, wherein generating pix-level masks from the status of placed modules and the next two modules to be placed comprises:
generating two position masks from the features of placed chips and the next two chips to be placed;
generating two wire masks from the features of placed modules and the next two modules to be placed; and
generating one view mask from the features of placed modules.

5. The method of claim 4, wherein generating two position masks from the features of placed chips and the next two chips to be place comprises:
acquiring the size and position of placed chips;
acquiring the size of the next two chips to be placed;
calculating all possible positions of the chip that will not overlap with the already placed chips with the next two chips to be placed separately;
marking all possible positions with 1 and other positions with 0 in the position masks.

6. The method of claim 4, wherein generating two wire masks from the features of placed chips and the next two chips to be placed comprises:
acquiring the size and position of placed chips;
acquiring the size of the next two chips to be placed;
acquiring each bounding box range for pins belonging to the same wire;
computing the wirelength increase when placing a chip in different positions; and
filling the wirelength increase in corresponding position of wire masks.

7. The method of claim 4, wherein generating one view mask from the features of placed chips comprises:
acquiring the size and position of placed chips;
computing the number of occupied matrix elements based on the size of the chip; and
marking all occupied elements with 1 and other elements with 0 in the view mask.

8. The method of claim 1, wherein extracting local and global features from masks by convolutional neural networks comprises:
extracting local features from masks by convolutional neural networks with small kernels;
extracting global features from masks by convolutional neural networks with large kernels; and
merging local and global features by convolutional neural networks.

9. The method of claim 8, wherein merging local and global features by convolutional neural networks comprises:
generating two position masks from the features of placed chips and the next two chips to be placed;
acquiring the local and global feature maps respectively;
merging features by convolutional neural networks with a lx1 kernel from a concatenated feature map;
removing all impossible positions according to the corresponding position mask; and
computing the probability action matrix by a softmax layer.

10. The method of claim 1, wherein selecting the placement position by merged features and congestion threshold comprises:
sampling one place position from the probability matrix with the corresponding probability;
computing the congestion after taking this placement action at the position;
re-sampling several place positions and computing the corresponding congestion if the congestion is greater than the congestion threshold;
selecting the position that has the minimum wirelength while meeting congestion requirements; and
placing the chip at the selected position and moving to the next placement step.
